(19) United States
(12) Patent Application Publication
(10) Pub. No.: US 2026/0330694 A1
(43) Pub. Date: Oct. 22, 2026

(54) 3D GAUSSIAN SPLAT CODING USING VIDEO-BASED POINT CLOUD COMPRESSION CODEC

(71) Applicant: Samsung Electronics Co., Ltd., Suwon-si (KR)

(72) Inventors: Madhukar Budagavi, Plano, TX (US); Rajan Laxman Joshi, San Diego, CA (US)

(21) Appl. No.: 19/650,054

(22) Filed: Apr. 16, 2026

Related U.S. Application Data
(60) Provisional application No. 63/792,818, filed on Apr. 22, 2025.

(51) Int. Cl. G06T 9/00; H03M 7/24

(52) U.S. Cl. CPC G06T 9/001; H03M 7/24

(57) ABSTRACT

An apparatus includes a communication interface configured to receive a compressed bitstream comprising 3D Gaussian Splats (3DGS) data and a processor operably coupled to the communication interface. The processor is configured to decode the compressed bitstream using a video decoder. The processor is also configured to retrieve the 3DGS data from raw patches included in a plurality of video frames of the decoded compressed bitstream, wherein the 3DGS data is included as integer values converted from original floating point values. The processor is also configured to reconstruct 3DGS information for rendering based on the 3DGS data.

### CROSS-REFERENCE TO RELATED APPLICATION AND PRIORITY CLAIM

This application claims priority under 35 U.S.C. § 119(e) to U.S. Provisional Patent Application No. 63/792,818 filed on Apr. 22, 2025, which is hereby incorporated by reference in its entirety.

### TECHNICAL FIELD

This disclosure relates generally to multimedia devices and processes. More specifically, this disclosure relates to 3D Gaussian splat coding using video-based point cloud compression codec.

### BACKGROUND

Three hundred sixty degree (360°) video and three dimensional (3D) volumetric video are emerging as new ways of experiencing immersive content due to the ready availability of powerful handheld devices such as smartphones. While 360° video enables an immersive “real life,” “being-there,” experience for consumers by capturing the 360° outside-in view of the world, 3D volumetric video can provide a complete six degrees of freedom (DoF) experience of being immersed and moving within the content. Users can interactively change their viewpoint and dynamically view any part of the captured scene or object they desire. Display and navigation sensors can track head movement of a user in real-time to determine the region of the 360° video or volumetric content that the user wants to view or interact with. Multimedia data that is 3D in nature, such as point clouds or 3D polygonal meshes, can be used in the immersive environment. This data can be stored in a video format and encoded and compressed for transmission as a bitstream to other devices.

### SUMMARY

This disclosure provides for 3D Gaussian splat coding using video-based point cloud compression codec.

In one embodiment, an apparatus includes a communication interface configured to receive a compressed bitstream comprising 3D Gaussian Splats (3DGS) data and a processor operably coupled to the communication interface. The processor is configured to decode the compressed bitstream using a video decoder. The processor is also configured to retrieve the 3DGS data from raw patches included in a plurality of video frames of the decoded compressed bitstream, wherein the 3DGS data is included as integer values converted from original floating point values. The processor is also configured to reconstruct 3DGS information for rendering based on the 3DGS data.

In another embodiment, a method includes receiving a compressed bitstream comprising 3D Gaussian Splats (3DGS) data. The method also includes decoding the compressed bitstream using a video decoder. The method also includes retrieving the 3DGS data from raw patches included in a plurality of video frames of the decoded compressed bitstream, wherein the 3DGS data is included as integer values converted from original floating point values. The method also includes reconstructing 3DGS information for rendering based on the 3DGS data.

In yet another embodiment, an apparatus includes a communication interface and a processor operably coupled to the communication interface. The processor is configured to retrieve 3D Gaussian Splats (3DGS) data for compressing into a compressed bitstream. The processor is also configured to convert floating point values of the 3DGS data into integer values. The processor is also configured to pack the integer values of the 3DGS data into raw patches included in a plurality of video frames. The processor is also configured to generate, by a video encoder using the plurality of video frames, the compressed bitstream comprising the 3DGS data. The processor is also configured to transmit, via the communication interface, the compressed bitstream to another apparatus.

Other technical features may be readily apparent to one skilled in the art from the following figures, descriptions, and claims.

Before undertaking the DETAILED DESCRIPTION below, it may be advantageous to set forth definitions of certain words and phrases used throughout this patent document. The term “couple” and its derivatives refer to any direct or indirect communication between two or more elements, whether or not those elements are in physical contact with one another. The terms “transmit,” “receive,” and “communicate,” as well as derivatives thereof, encompass both direct and indirect communication. The terms “include” and “comprise,” as well as derivatives thereof, mean inclusion without limitation. The term “or” is inclusive, meaning and/or. The phrase “associated with,” as well as derivatives thereof, means to include, be included within, interconnect with, contain, be contained within, connect to or with, couple to or with, be communicable with, cooperate with, interleave, juxtapose, be proximate to, be bound to or with, have, have a property of, have a relationship to or with, or the like. The term “controller” means any device, system, or part thereof that controls at least one operation. Such a controller may be implemented in hardware or a combination of hardware and software and/or firmware. The functionality associated with any particular controller may be centralized or distributed, whether locally or remotely. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

Moreover, various functions described below can be implemented or supported by one or more computer programs, each of which is formed from computer readable program code and embodied in a computer readable medium. The terms “application” and “program” refer to one or more computer programs, software components, sets of instructions, procedures, functions, objects, classes, instances, related data, or a portion thereof adapted for implementation in a suitable computer readable program code. The phrase “computer readable program code” includes any type of computer code, including source code, object code, and executable code. The phrase “computer readable medium” includes any type of medium capable of being accessed by a computer, such as read only memory (ROM), random access memory (RAM), a hard disk drive, a compact disc (CD), a digital video disc (DVD), or any other type of memory. A “non-transitory” computer readable medium excludes wired, wireless, optical, or other communication links that transport transitory electrical or other signals. A non-transitory computer readable medium includes media where data can be permanently stored and media where data can be stored and later overwritten, such as a rewritable optical disc or an erasable memory device.

Definitions for other certain words and phrases are provided throughout this patent document. Those of ordinary skill in the art should understand that in many if not most instances, such definitions apply to prior as well as future uses of such defined words and phrases.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 illustrates an example communication system in accordance with this disclosure

FIGS. 2 and 3 illustrate example electronic devices in accordance with this disclosure;

FIG. 4 illustrates an example graph representing an example floating point value to integer conversion in accordance with this disclosure;

FIG. 5 illustrates an example coordinates packing scheme for a geometry video frame in accordance with this disclosure;

FIG. 6 illustrates an example coordinates packing scheme for a geometry video frame including multiple RAW patches in accordance with this disclosure;

FIG. 7 illustrates an example scale value packing scheme for an attribute video frame in accordance with this disclosure;

FIG. 8 illustrates an example rotation value packing scheme for an attribute video frame in accordance with this disclosure;

FIG. 9 illustrates an example transparency value packing scheme for an attribute video frame in accordance with this disclosure;

FIG. 10 illustrates an example color value packing scheme for an attribute video frame in accordance with this disclosure;

FIG. 11 illustrates an example spherical harmonic value packing scheme for an attribute video frame in accordance with this disclosure;

FIG. 12 illustrates an example encoding method in accordance with this disclosure; and

FIG. 13 illustrates an example decoding method in accordance with this disclosure.

### DETAILED DESCRIPTION

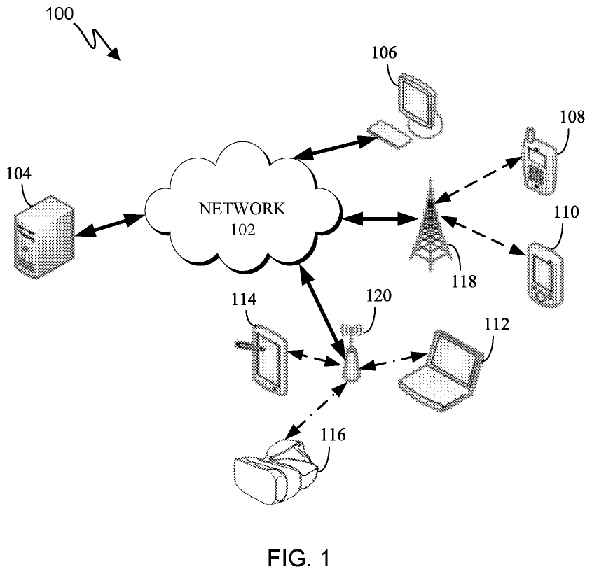

FIGS. 1 through 13, described below, and the various embodiments used to describe the principles of the present disclosure are by way of illustration only and should not be construed in any way to limit the scope of the disclosure. Those skilled in the art will understand that the principles of the present disclosure may be implemented in any type of suitably arranged device or system.

As noted above, three hundred sixty degree (360°) video and three dimensional (3D) volumetric video are emerging as new ways of experiencing immersive content due to the ready availability of powerful handheld devices such as smartphones. While 360° video enables an immersive “real life,” “being-there,” experience for consumers by capturing the 360° outside-in view of the world, 3D volumetric video can provide a complete six degrees of freedom (DoF) experience of being immersed and moving within the content. Users can interactively change their viewpoint and dynamically view any part of the captured scene or object they desire. Display and navigation sensors can track head movement of a user in real-time to determine the region of the 360° video or volumetric content that the user wants to view or interact with. Multimedia data that is 3D in nature, such as point clouds or 3D polygonal meshes, can be used in the immersive environment. This data can be stored in a video format and encoded and compressed for transmission as a bitstream to other devices.

A point cloud is a set of 3D points along with attributes such as color, normal directions, reflectivity, point-size, etc. that represent an object's surface or volume. Point clouds are common in a variety of applications such as gaming, 3D maps, visualizations, medical applications, augmented reality, virtual reality, autonomous driving, multi-view replay, and six degrees of freedom (DoF) immersive media, to name a few. Point clouds, if uncompressed, generally require a large amount of bandwidth for transmission. Due to the large bitrate requirement, point clouds are often compressed prior to transmission. Compressing a 3D object such as a point cloud, often requires specialized hardware. To avoid specialized hardware to compress a 3D point cloud, a 3D point cloud can be transformed into traditional two-dimensional (2D) frames and that can be compressed and later reconstructed and viewable to a user.

3D Gaussian Splats (3DGS) coding is quickly emerging to be an important format for 3D representation of objects and scene. 3DGS are a set of points with a 3D gaussian around each point. The 3D gaussian is defined by the attribute such as rotation, scale, color, transparency, and color spherical harmonic coefficients. The location of the point has to be transmitted as well. 3DGS, if uncompressed, generally require a large amount of bandwidth for transmission. Due to large bitrate requirements, a 3DGS needs to be compressed prior to transmission. Compressing a 3D object such as 3DGS often requires specialized hardware. To avoid specialized hardware to compress a 3DGS, a 3DGS can be transformed into traditional two-dimensional (2D) frames and that can be compressed and later be reconstructed and viewable to a user. Embodiments of this disclosure include packing the 3DGS data into raw patches of Video-based point cloud standard and use existing video codec standard implementations to compress the data.

Polygonal 3D meshes, especially triangular meshes, are another popular format for representing 3D objects. Meshes typically include a set of vertices, edges and faces that are used for representing the surface of 3D objects. Triangular meshes are simple polygonal meshes in which the faces are simple triangles covering the surface of the 3D object. Typically, there may be one or more attributes associated with the mesh. In one scenario, one or more attributes may be associated with each vertex in the mesh. For example, a texture attribute (RGB) may be associated with each vertex. In another scenario, each vertex may be associated with a pair of coordinates, (u, v). The (u, v) coordinates may point to a position in a texture map associated with the mesh. For example, the (u, v) coordinates may refer to row and column indices in the texture map, respectively. A mesh can be thought of as a point cloud with additional connectivity information.

The point cloud, 3DGS, or meshes may be dynamic, i.e., they may vary with time. In these cases, the point cloud, 3DGS, or mesh at a particular time instant may be referred to as a point cloud frame, a 3DGS frame, or a mesh frame, respectively. Since point clouds, 3DGS, and meshes contain a large amount of data, they require compression for efficient storage and transmission. This is particularly true for dynamic point clouds, 3DGS, and meshes, which may contain 60 frames or higher per second.

FIG. 1 illustrates an example communication system 100 in accordance with this disclosure. The embodiment of the communication system 100 shown in FIG. 1 is for illustration only. Other embodiments of the communication system 100 can be used without departing from the scope of this disclosure.

As shown in FIG. 1, the communication system 100 includes a network 102 that facilitates communication between various components in the communication system 100. For example, the network 102 can communicate IP packets, frame relay frames, Asynchronous Transfer Mode (ATM) cells, or other information between network addresses. The network 102 includes one or more local area networks (LANs), metropolitan area networks (MANs), wide area networks (WANs), all or a portion of a global network such as the Internet, or any other communication system or systems at one or more locations.

In this example, the network 102 facilitates communications between a server 104 and various client devices 106-116. The client devices 106-116 may be, for example, a smartphone, a tablet computer, a laptop, a personal computer, a TV, an interactive display, a wearable device, a HMD, or the like. The server 104 can represent one or more servers. Each server 104 includes any suitable computing or processing device that can provide computing services for one or more client devices, such as the client devices 106-116. Each server 104 could, for example, include one or more processing devices, one or more memories storing instructions and data, and one or more network interfaces facilitating communication over the network 102. As described in more detail below, the server 104 can transmit a compressed bitstream, representing a point cloud, 3DGS, or mesh, to one or more display devices, such as a client device 106-116. In certain embodiments, each server 104 can include an encoder.

Each client device 106-116 represents any suitable computing or processing device that interacts with at least one server (such as the server 104) or other computing device(s) over the network 102. The client devices 106-116 include a desktop computer 106, a mobile telephone or mobile device 108 (such as a smartphone), a PDA 110, a laptop computer 112, a tablet computer 114, and a HMD 116. However, any other or additional client devices could be used in the communication system 100. Smartphones represent a class of mobile devices 108 that are handheld devices with mobile operating systems and integrated mobile broadband cellular network connections for voice, short message service (SMS), and Internet data communications. The HMD 116 can display 360° scenes including one or more dynamic or static 3D point clouds. In certain embodiments, any of the client devices 106-116 can include an encoder, decoder, or both. For example, the mobile device 108 can record a 3D volumetric video and then encode the video enabling the video to be transmitted to one of the client devices 106-116. In another example, the laptop computer 112 can be used to generate a 3D point cloud, 3DGS, or mesh, which is then encoded and transmitted to one of the client devices 106-116.

In this example, some client devices 108-116 communicate indirectly with the network 102. For example, the mobile device 108 and PDA 110 communicate via one or more base stations 118, such as cellular base stations or eNodeBs (eNBs). Also, the laptop computer 112, the tablet computer 114, and the HMD 116 communicate via one or more wireless access points 120, such as IEEE 802.11 wireless access points. Note that these are for illustration only and that each client device 106-116 could communicate directly with the network 102 or indirectly with the network 102 via any suitable intermediate device(s) or network(s). In certain embodiments, the server 104 or any client device 106-116 can be used to compress a point cloud, 3DGS, or mesh, generate a bitstream that represents the point cloud, 3DGS, or mesh, and transmit the bitstream to another client device such as any client device 106-116.

In certain embodiments, any of the client devices 106-114 transmit information securely and efficiently to another device, such as, for example, the server 104. Also, any of the client devices 106-116 can trigger the information transmission between itself and the server 104. Any of the client devices 106-114 can function as a VR display when attached to a headset via brackets, and function similar to HMD 116. For example, the mobile device 108 when attached to a bracket system and worn over the eyes of a user can function similarly as the HMD 116. The mobile device 108 (or any other client device 106-116) can trigger the information transmission between itself and the server 104.

In certain embodiments, any of the client devices 106-116 or the server 104 can create a 3D point cloud, 3DGS, or mesh, compress a 3D point cloud, 3DGS, or mesh, transmit a 3D point cloud, 3DGS, or mesh, receive a 3D point cloud, 3DGS, or mesh, decode a 3D point cloud, 3DGS, or mesh, render a 3D point cloud, 3DGS, or mesh, or a combination thereof. For example, the server 104 can compress a 3D point cloud, 3DGS, or mesh to generate a bitstream and then transmit the bitstream to one or more of the client devices 106-116. As another example, one of the client devices 106-116 can compress a 3D point cloud, 3DGS, or mesh to generate a bitstream and then transmit the bitstream to another one of the client devices 106-116 or to the server 104. In accordance with this disclosure, the server 104 and/or the client devices 106-116 can process compressed bitstreams comprising volumetric data, determine, from two or more volumetric data types, a type of volumetric data to be rendered, and retrieve the volumetric data corresponding to the determined type of volumetric data from the compressed bitstream to reconstruct the volumetric data for rendering.

Although FIG. 1 illustrates one example of a communication system 100, various changes can be made to FIG. 1. For example, the communication system 100 could include any number of each component in any suitable arrangement. In general, computing and communication systems come in a wide variety of configurations, and FIG. 1 does not limit the scope of this disclosure to any particular configuration. While FIG. 1 illustrates one operational environment in which various features disclosed in this patent document can be used, these features could be used in any other suitable system.

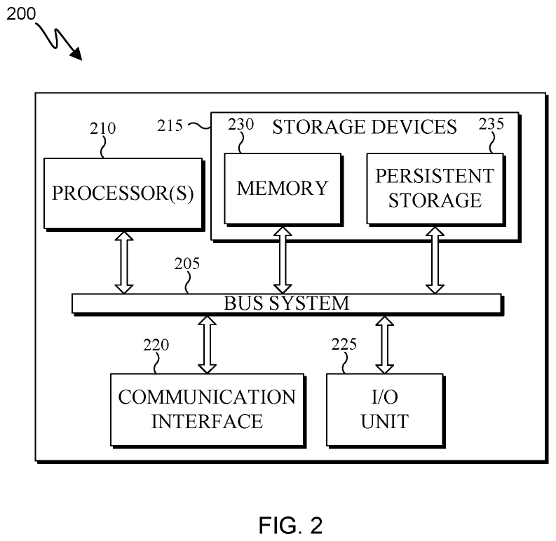

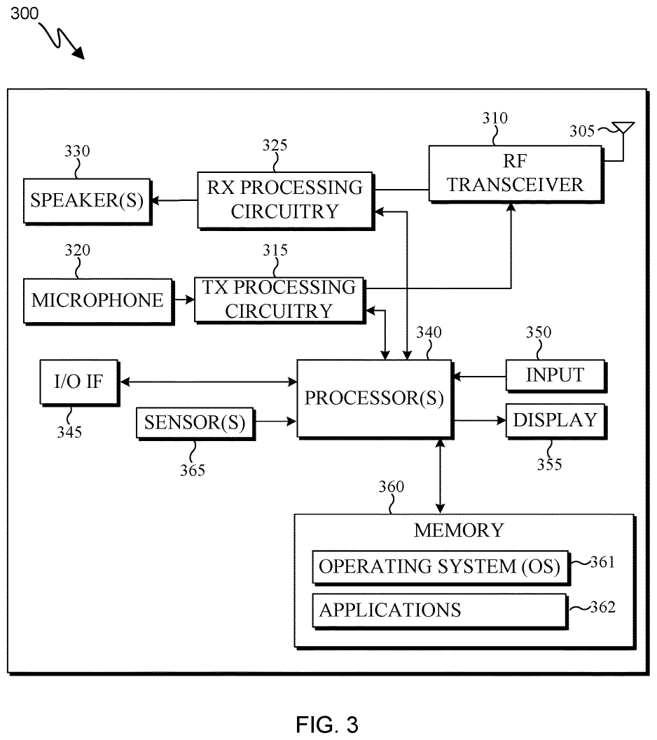

FIGS. 2 and 3 illustrate example electronic devices in accordance with this disclosure. In particular, FIG. 2 illustrates an example server 200, and the server 200 could represent the server 104 in FIG. 1. The server 200 can represent one or more encoders, decoders, local servers, remote servers, clustered computers, and components that act as a single pool of seamless resources, a cloud-based server, and the like. The server 200 can be accessed by one or more of the client devices 106-116 of FIG. 1 or another server.

As shown in FIG. 2, the server 200 can represent one or more local servers, one or more compression servers, or one or more encoding servers, such as an encoder. In certain embodiments, the encoder can perform decoding. As shown in FIG. 2, the server 200 includes a bus system 205 that supports communication between at least one processing device (such as a processor 210), at least one storage device 215, at least one communications interface 220, and at least one input/output (I/O) unit 225.

The processor 210 executes instructions that can be stored in a memory 230. The processor 210 can include any suitable number(s) and type(s) of processors or other devices in any suitable arrangement. Example types of processors 210 include microprocessors, microcontrollers, digital signal processors, field programmable gate arrays, application specific integrated circuits, and discrete circuitry.

In certain embodiments, the processor 210 can encode a 3D point cloud, 3DGS, or mesh stored within the storage devices 215. In certain embodiments, encoding a 3D point cloud also decodes the 3D point cloud, 3DGS, or mesh to ensure that when the point cloud, 3DGS, or mesh is reconstructed, the reconstructed 3D point cloud, 3DGS, or mesh matches the 3D point cloud, 3DGS, or mesh prior to the encoding. In certain embodiments, the processor 210 can process compressed bitstreams comprising volumetric data, determine, from two or more volumetric data types, a type of volumetric data to be rendered, and retrieve the volumetric data corresponding to the determined type of volumetric data from the compressed bitstream to reconstruct the volumetric data for rendering.

The memory 230 and a persistent storage 235 are examples of storage devices 215 that represent any structure(s) capable of storing and facilitating retrieval of information (such as data, program code, or other suitable information on a temporary or permanent basis). The memory 230 can represent a random access memory or any other suitable volatile or non-volatile storage device(s). For example, the instructions stored in the memory 230 can include instructions for decomposing a point cloud into patches, instructions for packing the patches on 2D frames, instructions for compressing the 2D frames, as well as instructions for encoding 2D frames in a certain order in order to generate a bitstream. The instructions stored in the memory 230 can also include instructions for rendering the point cloud on an omnidirectional 360° scene, as viewed through a VR headset, such as HMD 116 of FIG. 1. The persistent storage 235 can contain one or more components or devices supporting longer-term storage of data, such as a read only memory, hard drive, Flash memory, or optical disc.

The communications interface 220 supports communications with other systems or devices. For example, the communications interface 220 could include a network interface card or a wireless transceiver facilitating communications over the network 102 of FIG. 1. The communications interface 220 can support communications through any suitable physical or wireless communication link(s). For example, the communications interface 220 can transmit a bitstream containing a 3D point cloud to another device such as one of the client devices 106-116.

The I/O unit 225 allows for input and output of data. For example, the I/O unit 225 can provide a connection for user input through a keyboard, mouse, keypad, touchscreen, or other suitable input device. The I/O unit 225 can also send output to a display, printer, or other suitable output device. Note, however, that the I/O unit 225 can be omitted, such as when I/O interactions with the server 200 occur via a network connection.

Note that while FIG. 2 is described as representing the server 104 of FIG. 1, the same or similar structure could be used in one or more of the various client devices 106-116. For example, a desktop computer 106 or a laptop computer 112 could have the same or similar structure as that shown in FIG. 2.

FIG. 3 illustrates an example electronic device 300, and the electronic device 300 could represent one or more of the client devices 106-116 in FIG. 1. The electronic device 300 can be a mobile communication device, such as, for example, a mobile station, a subscriber station, a wireless terminal, a desktop computer (similar to the desktop computer 106 of FIG. 1), a portable electronic device (similar to the mobile device 108, the PDA 110, the laptop computer 112, the tablet computer 114, or the HMD 116 of FIG. 1), and the like. In certain embodiments, one or more of the client devices 106-116 of FIG. 1 can include the same or similar configuration as the electronic device 300. In certain embodiments, the electronic device 300 is an encoder, a decoder, or both. For example, the electronic device 300 is usable with data transfer, image or video compression, image or video decompression, encoding, decoding, and media rendering applications.

As shown in FIG. 3, the electronic device 300 includes an antenna 305, a radio-frequency (RF) transceiver 310, transmit (TX) processing circuitry 315, a microphone 320, and receive (RX) processing circuitry 325. The RF transceiver 310 can include, for example, a RF transceiver, a BLUETOOTH transceiver, a WI-FI transceiver, a ZIGBEE transceiver, an infrared transceiver, and various other wireless communication signals. The electronic device 300 also includes a speaker 330, a processor 340, an input/output (I/O) interface (IF) 345, an input 350, a display 355, a memory 360, and a sensor(s) 365. The memory 360 includes an operating system (OS) 361, and one or more applications 362.

The RF transceiver 310 receives from the antenna 305, an incoming RF signal transmitted from an access point (such as a base station, WI-FI router, or BLUETOOTH device) or other device of the network 102 (such as a WI-FI, BLUETOOTH, cellular, 5G, LTE, LTE-A, WiMAX, or any other type of wireless network). The RF transceiver 310 down-converts the incoming RF signal to generate an intermediate frequency or baseband signal. The intermediate frequency or baseband signal is sent to the RX processing circuitry 325 that generates a processed baseband signal by filtering, decoding, and/or digitizing the baseband or intermediate frequency signal. The RX processing circuitry 325 transmits the processed baseband signal to the speaker 330 (such as for voice data) or to the processor 340 for further processing (such as for web browsing data).

The TX processing circuitry 315 receives analog or digital voice data from the microphone 320 or other outgoing baseband data from the processor 340. The outgoing baseband data can include web data, e-mail, or interactive video game data. The TX processing circuitry 315 encodes, multiplexes, and/or digitizes the outgoing baseband data to generate a processed baseband or intermediate frequency signal. The RF transceiver 310 receives the outgoing processed baseband or intermediate frequency signal from the TX processing circuitry 315 and up-converts the baseband or intermediate frequency signal to an RF signal that is transmitted via the antenna 305.

The processor 340 can include one or more processors or other processing devices. The processor 340 can execute instructions that are stored in the memory 360, such as the OS 361 in order to control the overall operation of the electronic device 300. For example, the processor 340 could control the reception of forward channel signals and the transmission of reverse channel signals by the RF transceiver 310, the RX processing circuitry 325, and the TX processing circuitry 315 in accordance with well-known principles. The processor 340 can include any suitable number(s) and type(s) of processors or other devices in any suitable arrangement. For example, in certain embodiments, the processor 340 includes at least one microprocessor or microcontroller. Example types of the processor 340 include microprocessors, microcontrollers, digital signal processors, field programmable gate arrays, application specific integrated circuits, and discrete circuitry.

The processor 340 is also capable of executing other processes and programs resident in the memory 360, such as operations that receive and store data. The processor 340 can move data into or out of the memory 360 as required by an executing process. In certain embodiments, the processor 340 is configured to execute the one or more applications 362 based on the OS 361 or in response to signals received from external source(s) or an operator. Example, applications 362 can include an encoder, a decoder, a VR or AR application, a camera application (for still images and videos), a video phone call application, an email client, a social media client, an SMS messaging client, a virtual assistant, and the like. In certain embodiments, the processor 340 is configured to receive and transmit media content.

In certain embodiments, the processor 340 can process compressed bitstreams comprising volumetric data, determine, from two or more volumetric data types, a type of volumetric data to be rendered, and retrieve the volumetric data corresponding to the determined type of volumetric data from the compressed bitstream to reconstruct the volumetric data for rendering.

The processor 340 is also coupled to the I/O interface 345 that provides the electronic device 300 with the ability to connect to other devices, such as client devices 106-114. The I/O interface 345 is the communication path between these accessories and the processor 340.

The processor 340 is also coupled to the input 350 and the display 355. The operator of the electronic device 300 can use the input 350 to enter data or inputs into the electronic device 300. The input 350 can be a keyboard, touchscreen, mouse, track ball, voice input, or other device capable of acting as a user interface to allow a user to interact with the electronic device 300. For example, the input 350 can include voice recognition processing, thereby allowing a user to input a voice command. In another example, the input 350 can include a touch panel, a (digital) pen sensor, a key, or an ultrasonic input device. The touch panel can recognize, for example, a touch input in at least one scheme, such as a capacitive scheme, a pressure sensitive scheme, an infrared scheme, or an ultrasonic scheme. The input 350 can be associated with the sensor(s) 365 and/or a camera by providing additional input to the processor 340. In certain embodiments, the sensor 365 includes one or more inertial measurement units (IMUs) (such as accelerometers, gyroscope, and magnetometer), motion sensors, optical sensors, cameras, pressure sensors, heart rate sensors, altimeter, and the like. The input 350 can also include a control circuit. In the capacitive scheme, the input 350 can recognize touch or proximity.

The display 355 can be a liquid crystal display (LCD), light-emitting diode (LED) display, organic LED (OLED), active matrix OLED (AMOLED), or other display capable of rendering text and/or graphics, such as from websites, videos, games, images, and the like. The display 355 can be sized to fit within an HMD. The display 355 can be a singular display screen or multiple display screens capable of creating a stereoscopic display. In certain embodiments, the display 355 is a heads-up display (HUD). The display 355 can display 3D objects, such as a 3D point cloud, 3DGS, or mesh.

The memory 360 is coupled to the processor 340. Part of the memory 360 could include a RAM, and another part of the memory 360 could include a Flash memory or other ROM. The memory 360 can include persistent storage (not shown) that represents any structure(s) capable of storing and facilitating retrieval of information (such as data, program code, and/or other suitable information). The memory 360 can contain one or more components or devices supporting longer-term storage of data, such as a read only memory, hard drive, Flash memory, or optical disc. The memory 360 also can contain media content. The media content can include various types of media such as images, videos, three-dimensional content, VR content, AR content, 3D point clouds,, 3DGS, meshes, and the like.

The electronic device 300 further includes one or more sensors 365 that can meter a physical quantity or detect an activation state of the electronic device 300 and convert metered or detected information into an electrical signal. For example, the sensor 365 can include one or more buttons for touch input, a camera, a gesture sensor, an IMU sensors (such as a gyroscope or gyro sensor and an accelerometer), an eye tracking sensor, an air pressure sensor, a magnetic sensor or magnetometer, a grip sensor, a proximity sensor, a color sensor, a bio-physical sensor, a temperature/humidity sensor, an illumination sensor, an Ultraviolet (UV) sensor, an Electromyography (EMG) sensor, an Electroencephalogram (EEG) sensor, an Electrocardiogram (ECG) sensor, an IR sensor, an ultrasound sensor, an iris sensor, a fingerprint sensor, a color sensor (such as a Red Green Blue (RGB) sensor), and the like. The sensor 365 can further include control circuits for controlling any of the sensors included therein.

As discussed in greater detail below, one or more of these sensor(s) 365 may be used to control a user interface (UI), detect UI inputs, determine the orientation and facing the direction of the user for three-dimensional content display identification, and the like. Any of these sensor(s) 365 may be located within the electronic device 300, within a secondary device operably connected to the electronic device 300, within a headset configured to hold the electronic device 300, or in a singular device where the electronic device 300 includes a headset.

The electronic device 300 can create media content such as generate a virtual object or capture (or record) content through a camera. The electronic device 300 can encode the media content to generate a bitstream, such that the bitstream can be transmitted directly to another electronic device or indirectly such as through the network 102 of FIG. 1. The electronic device 300 can receive a bitstream directly from another electronic device or indirectly such as through the network 102 of FIG. 1.

Although FIGS. 2 and 3 illustrate examples of electronic devices, various changes can be made to FIGS. 2 and 3. For example, various components in FIGS. 2 and 3 could be combined, further subdivided, or omitted and additional components could be added according to particular needs. As a particular example, the processor 340 could be divided into multiple processors, such as one or more central processing units (CPUs) and one or more graphics processing units (GPUs). In addition, as with computing and communication, electronic devices and servers can come in a wide variety of configurations, and FIGS. 2 and 3 do not limit this disclosure to any particular electronic device or server.

Various standards have been proposed with respect to compression of 3DGS. This disclosure relates to compression and decompression of 3DGS using the Video-based Point Cloud Compression (V-PCC) standard. The following documents are hereby incorporated by reference in their entirety as if fully set forth herein:
ISO/IEC FDIS 23090-5 Visual Volumetric Video-based Coding and Video-based Point Cloud Compression (V-PCC), ISO/IEC SC29 WG07 N19579, September 2021; and
ISO/IEC DIS 23090-5 V3C 4th edition, ISO/IEC SC29 WG07 N01154, April 2025.

3DGS are used to represent 3D objects/scene. They consist of millions of overlapping 3D gaussian of varying ellipsoidal shapes, orientations, and attributes. 3DGS provides a photo realistic representation of a 3D object/scene. It can be learned from a small sample of images quickly and also rendered in real-time.

Each 3D gaussian splat/point is represented by:
3 position values (x-, y-, and z-coordinates)
3 scale values
4 rotation values (rotation value of the ellipsoid)
1 transparency value (transparency of the ellipsoid)
3 color values (direct current (DC) values of spherical harmonics)
45 spherical harmonic values (can be packed into one frame or split across multiple)

Each of these quantities is typically represented by a 32-bit floating point value requiring 236 bytes per point/splat. A 3DGS picture (scene) of 7 million splats/points can require 1.652 GB. 3DGS videos will require even more bandwidth. Hence, compression of 3DGS is essential. The spherical harmonic values refer to special functions defined on the surface of a sphere. They are often employed in solving partial differential equations in various fields. Since the spherical harmonics form a complete set of orthogonal functions and thus an orthonormal basis, certain functions defined on the surface of a sphere can be written as a sum of these spherical harmonics.

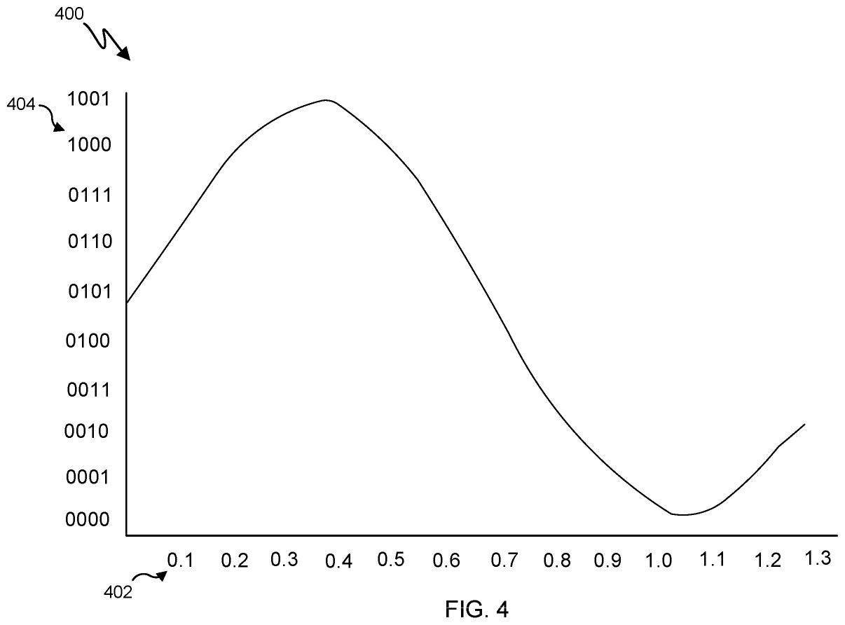

FIG. 4 illustrates an example graph 400 representing an example floating point value to integer conversion in accordance with this disclosure. The graph 400 illustrated in FIG. 4 is for illustration only. FIG. 4 does not limit the scope of this disclosure to any particular implementation of a floating point value to integer conversion.

In various embodiments of this disclosure, to decrease the size of the 3DGS data, the 3DGS floating point value data is converted to fixed point integers and packed into video frames. As shown in FIG. 4, to convert the floating point values to integer values, the various floating point values 402 can be converted to various integers via a mapping of the values to the integers, where the integers are binary numbers as shown in FIG. 4.

For example, in some embodiments, given 3DGS data with 7 million points and 7million x y z coordinates, each x, y, z coordinate has a minimum and a maximum. If that range is split into 1024 regions (2 to the power of 10) any floating point value falling into a particular region can use a specific integer.

Although FIG. 4 illustrates one example graph 400 representing an example floating point value to integer conversion, various changes may be made to FIG. 4. For example, it will be understood that the particular values used in FIG. 4 are for illustrative purposes only, and only values can be used.

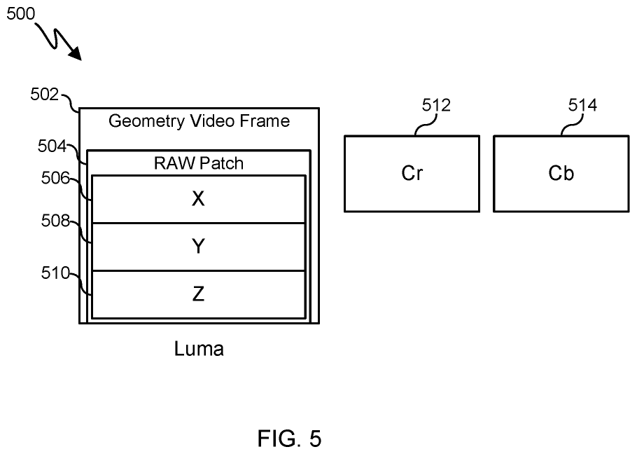

FIG. 5 illustrates an example coordinates packing scheme 500 for a geometry video frame 502 in accordance with this disclosure. The packing scheme 500 illustrated in FIG. 5 is for illustration only. FIG. 5 does not limit the scope of this disclosure to any particular implementation of a coordinates packing scheme. For ease of explanation, the packing scheme 500 of FIG. 5 may be described as being used by the electronic device 300 of FIG. 3. However, the packing scheme 500 may be used with any other suitable system and any other suitable electronic device.

FIG. 5 shows an example of how the position values (x-, y- and z-coordinates) of 3DGS points/splats are packed into the geometry video frame 502 using the V-PCC standard. In various embodiments, V-PCC can be adapted to support use of a RAW patch 504 where the geometry data (x-coordinates 506, y-coordinates 508, and z-coordinates 510) of a point are directly stored into a video frame sequentially one after the other in a raster scan order. In some embodiments, the RAW patch 504 can cover the whole geometry video frame 502. In some embodiments, the RAW patch 504 can be a part of the geometry video frame 502. In some embodiments, the geometry video frame 502 can include a single RAW patch 504, which covers the position x-, y- and z-coordinates of all the 3D Gaussians in the 3DGS frame. As also shown in FIG. 5, the geometry video frame 502 can include or have associated therewith a chroma-red (Cr) component 512 and a chroma-blue (Cb) component 514. In video frames, Cb and Cr components are color-difference components in the YCbCr color space, representing the blue-difference (B-Y) and the red different (R-Y) signals.

Although FIG. 5 illustrates one example of a coordinates packing scheme 500 for a geometry video frame 502, various changes may be made to FIG. 5. For example, the geometry video frame 502 may include other data in addition to that shown in FIG. 5.

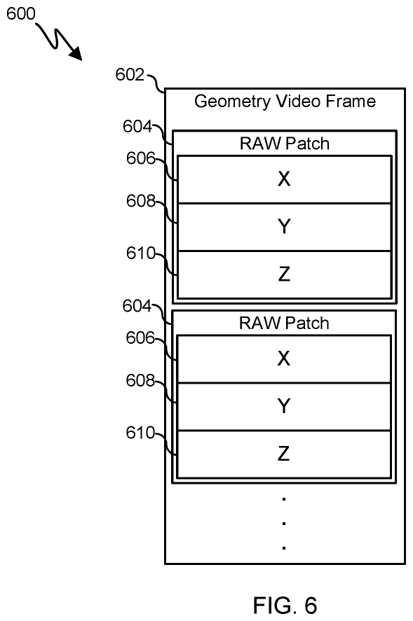

FIG. 6 illustrates an example coordinates packing scheme 600 for a geometry video frame 602 including multiple RAW patches in accordance with this disclosure. The packing scheme 600 illustrated in FIG. 6 is for illustration only. FIG. 6 does not limit the scope of this disclosure to any particular implementation of a coordinates packing scheme. For ease of explanation, the packing scheme 600 of FIG. 6 may be described as being used by the electronic device 300 of FIG. 3. However, the packing scheme 600 may be used with any other suitable system and any other suitable electronic device.

In various embodiments, multiple RAW patches 604 can be used. Consider that the geometry video codec bitdepth is B. Then, on the encoder side, the 3D space containing the Gaussian splats is divided into cubes of size 2^{B}×2^{B}×2^{B}. A RAW patch 604 can be generated for each cube. Due to the size of the cube, the x-coordinates 606, the y-coordinates 608, and the z-coordinates 610 for each Gaussian splat located within that cube can be represented by B bits. The x-, y-, and z-coordinates 606, 608, 610 along with the 3D offsets associated with each patch can define the location of each Gaussian splat within that cube. Thus, the bits representing each ellipsoid of a 3DGS get stored in cube data and the multiple RAW patches 504 in geometry video frame 600 store this cube data.

Although FIG. 6 illustrates one example of a coordinates packing scheme 600 for a geometry video frame 602 including multiple RAW patches 604, various changes may be made to FIG. 6. For example, the geometry video frame 602 may include other data in addition to that shown in FIG. 6. For instance, it will be understood that the geometry video frame 602 can include or have associated therewith Cr and Cb components.

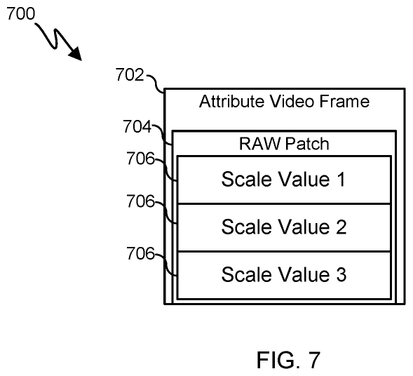

FIG. 7 illustrates an example scale value packing scheme 700 for an attribute video frame 702 in accordance with this disclosure. The packing scheme 700 illustrated in FIG. 7 is for illustration only. FIG. 7 does not limit the scope of this disclosure to any particular implementation of a scale value packing scheme. For ease of explanation, the packing scheme 700 of FIG. 7 may be described as being used by the electronic device 300 of FIG. 3. However, the packing scheme 700 may be used with any other suitable system and any other suitable electronic device.

In various embodiments, other 3DGS attributes such as those described hereinabove can be quantized and stored in their respective V-PCC attribute videos. They can be stored in the corresponding RAW patch locations in their respective V-PCC attribute videos. For example, as shown in FIG. 7, scale values 706 can be stored in a RAW patch 704 of the attribute video frame 702 for transmission to and decoding by an electronic device to reconstruct 3DGS data from a compressed bitstream.

In various embodiments, if multiple patches is enabled, then the scale information can be stored in multiple RAW patches of the attribute video frame. Such a packing arrangement using multiple RAW patches can be similar to that described with respect to FIG. 6, but for the scale values of the attribute video frame.

Although FIG. 7 illustrates one example of a scale value packing scheme 700 for an attribute video frame 702, various changes may be made to FIG. 7. For example, the attribute video frame 702 may include other data in addition to that shown in FIG. 7.

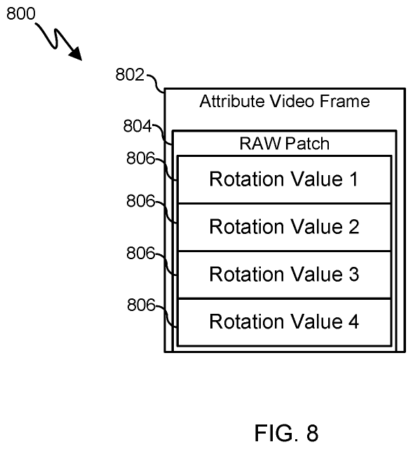

FIG. 8 illustrates an example rotation value packing scheme 800 for an attribute video frame 802 in accordance with this disclosure. The packing scheme 800 illustrated in FIG. 8 is for illustration only. FIG. 8 does not limit the scope of this disclosure to any particular implementation of a rotation value packing scheme. For ease of explanation, the packing scheme 800 of FIG. 8 may be described as being used by the electronic device 300 of FIG. 3. However, the packing scheme 800 may be used with any other suitable system and any other suitable electronic device.

As explained herein, in various embodiments, other 3DGS attributes such as those described hereinabove can be quantized and stored in their respective V-PCC attribute videos. They can be stored in the corresponding RAW patch locations in their respective V-PCC attribute videos. For example, as shown in FIG. 8, rotation values 806 can be stored in a RAW patch 804 of the attribute video frame 802 for transmission to and decoding by an electronic device to reconstruct 3DGS data from a compressed bitstream.

In various embodiments, if multiple patches is enabled, then the rotation information can be stored in multiple RAW patches of the attribute video frame. Such a packing arrangement using multiple RAW patches can be similar to that described with respect to FIG. 6, but for the rotation values of the attribute video frame.

Although FIG. 8 illustrates one example of a rotation value packing scheme 800 for an attribute video frame 802, various changes may be made to FIG. 8. For example, the attribute video frame 802 may include other data in addition to that shown in FIG. 8.

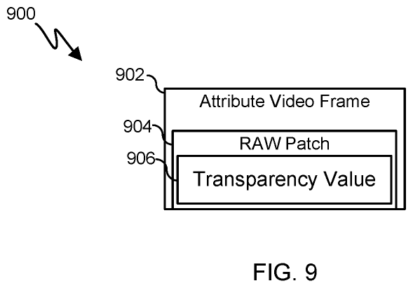

FIG. 9 illustrates an example transparency value packing scheme 900 for an attribute video frame 902 in accordance with this disclosure. The packing scheme 900 illustrated in FIG. 9 is for illustration only. FIG. 9 does not limit the scope of this disclosure to any particular implementation of a transparency value packing scheme. For ease of explanation, the packing scheme 900 of FIG. 9 may be described as being used by the electronic device 300 of FIG. 3. However, the packing scheme 900 may be used with any other suitable system and any other suitable electronic device.

As explained herein, in various embodiments, other 3DGS attributes such as those described hereinabove can be quantized and stored in their respective V-PCC attribute videos. They can be stored in the corresponding RAW patch locations in their respective V-PCC attribute videos. For example, as shown in FIG. 9, the transparency value 906 can be stored in a RAW patch 904 of the attribute video frame 902 for transmission to and decoding by an electronic device to reconstruct 3DGS data from a compressed bitstream.

In various embodiments, if multiple patches is enabled, then the transparency information can be stored in multiple RAW patches of the attribute video frame. Such a packing arrangement using multiple RAW patches can be similar to that described with respect to FIG. 6, but for the transparency value of the attribute video frame.

Although FIG. 9 illustrates one example of a transparency value packing scheme 900 for an attribute video frame 902, various changes may be made to FIG. 9. For example, the attribute video frame 902 may include other data in addition to that shown in FIG. 9.

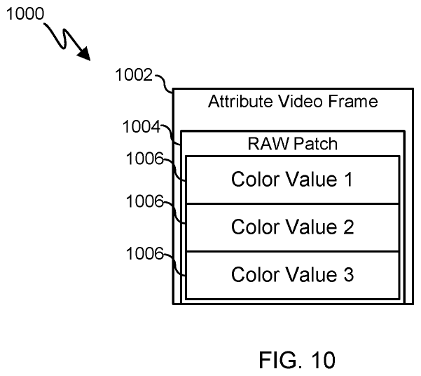

FIG. 10 illustrates an example color value packing scheme 1000 for an attribute video frame 1002 in accordance with this disclosure. The packing scheme 1000 illustrated in FIG. 10 is for illustration only. FIG. 10 does not limit the scope of this disclosure to any particular implementation of a color value packing scheme. For ease of explanation, the packing scheme 1000 of FIG. 10 may be described as being used by the electronic device 300 of FIG. 3. However, the packing scheme 1000 may be used with any other suitable system and any other suitable electronic device.

As explained herein, in various embodiments, other 3DGS attributes such as those described hereinabove can be quantized and stored in their respective V-PCC attribute videos. They can be stored in the corresponding RAW patch locations in their respective V-PCC attribute videos. For example, as shown in FIG. 10, color values 1006 can be stored in a RAW patch 1004 of the attribute video frame 1002 for transmission to and decoding by an electronic device to reconstruct 3DGS data from a compressed bitstream.

In various embodiments, if multiple patches is enabled, then the color information can be stored in multiple RAW patches of the attribute video frame. Such a packing arrangement using multiple RAW patches can be similar to that described with respect to FIG. 6, but for the color values of the attribute video frame.

Although FIG. 10 illustrates one example of a color value packing scheme 1000 for an attribute video frame 1002, various changes may be made to FIG. 10. For example, the attribute video frame 1002 may include other data in addition to that shown in FIG. 10.

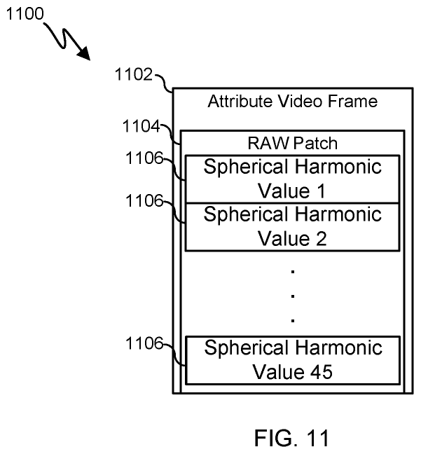

FIG. 11 illustrates an example spherical harmonic value packing scheme 1100 for an attribute video frame 1102 in accordance with this disclosure. The packing scheme 1100 illustrated in FIG. 11 is for illustration only. FIG. 11 does not limit the scope of this disclosure to any particular implementation of a spherical harmonic value packing scheme. For ease of explanation, the packing scheme 1100 of FIG. 11 may be described as being used by the electronic device 300 of FIG. 3. However, the packing scheme 1100 may be used with any other suitable system and any other suitable electronic device.

As explained herein, in various embodiments, other 3DGS attributes such as those described hereinabove can be quantized and stored in their respective V-PCC attribute videos. They can be stored in the corresponding RAW patch locations in their respective V-PCC attribute videos. For example, as shown in FIG. 11, spherical harmonic values 1106 can be stored in a RAW patch 1104 of the attribute video frame 1102 for transmission to and decoding by an electronic device to reconstruct 3DGS data from a compressed bitstream.

In various embodiments, if multiple patches is enabled, then the spherical harmonic information can be stored in multiple RAW patches of the attribute video frame. Such a packing arrangement using multiple RAW patches can be similar to that described with respect to FIG. 6, but for the spherical harmonic values of the attribute video frame.

Although FIG. 11 illustrates one example of a spherical harmonic value packing scheme 1100 for an attribute video frame 1102, various changes may be made to FIG. 11. For example, the attribute video frame 1102 may include other data in addition to that shown in FIG. 11.

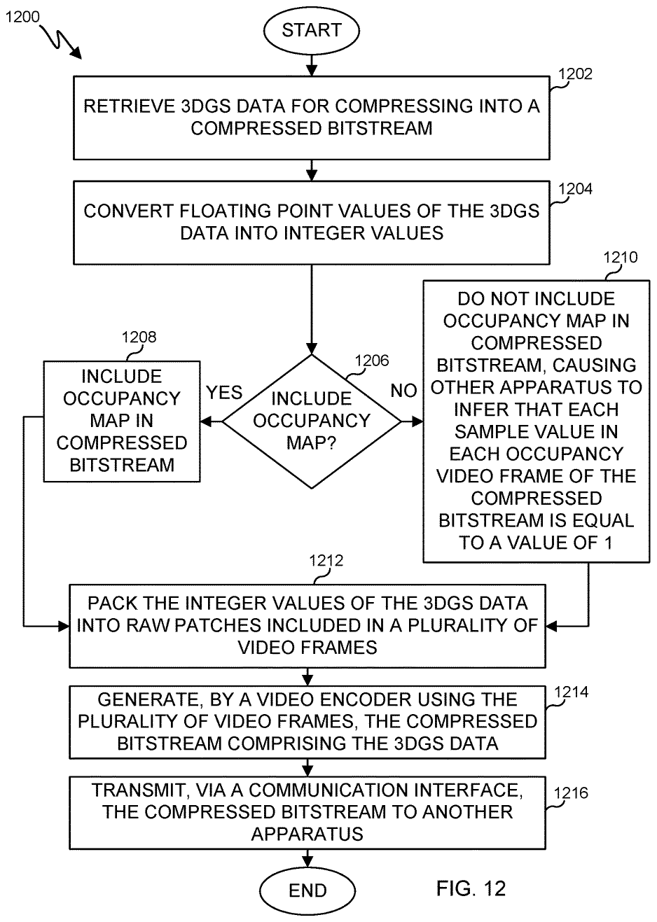

FIG. 12 illustrates an example encoding method 1200 in accordance with this disclosure. For ease of explanation, the method 1200 of FIG. 12 is described as being performed using the electronic device 300 of FIG. 3. However, the method 1200 may be used with any other suitable system and any other suitable electronic device.

As shown in FIG. 12, at step 1202, 3D Gaussian Splats (3DGS) data is retrieved for compressing into a compressed bitstream. At step 1204, floating point values of the 3DGS data are converted into integer values, such as described in this disclosure with respect to FIG. 4. At step 1206, it is determined whether to include an occupancy map in the compressed bitstream. An occupancy map can be included in V-PCC bitstreams to indicate where valid (value of 1) and invalid (value of 0) pixels are located in the image(s). However, in various implementations, use of an occupancy map in 3DGS data streams may be not needed and/or redundant, as pixel locations can be provided in 3DGS data streams. Therefore, in various embodiments of this disclosure, the V-PCC standard can be modified so that if an occupancy video/map is not present, each sample value in each occupancy video frame is inferred to be equal to 1.

If, at step 1206, it is determined to include an occupancy map, at step 1208 the occupancy map is included in the compressed bitstream, and the method 1200 moves to step 1212. If, at step 1206, it is determined to not include an occupancy map, at step 1210 the occupancy map is not included in the compressed bitstream, which will cause another apparatus that receives and decodes the compressed bitstream to infer that each sample value in each occupancy video frame of the compressed bitstream is equal to a value of 1, indicating that each pixel is valid. The method 1200 then moves to step 1212.

At step 1212, the integer values of the 3DGS data are packed into RAW patches included in a plurality of video frames. At step 1214, the processor generates, by a video encoder using the plurality of video frames, the compressed bitstream including the 3DGS data. The video encoder can be a V-PCC video encoder. The compressed bitstream can be decoded using a V-PCC video decoder to get the decoded video frames. As described in this disclosure, in various embodiments, the plurality of video frames can include a geometry video frame, and a raw patch of the geometry video frame can include x, y, and z coordinates of the 3DGS data. As described in this disclosure, in various embodiments, the x, y, and z coordinates of the 3DGS data in the raw patch of the geometry video frame can correspond to all 3D Gaussians in a 3DGS frame. As described in this disclosure, in various embodiments, a 3D space associated with the 3DGS data can be divided into cubes, the plurality of video frames can include a geometry video frame, the geometry video frame can include a plurality of raw patches, and each raw patch of the plurality of raw patches can include data for one of the cubes.

As described in this disclosure, in various embodiments, the plurality of video frames can include attribute video frames, and wherein each attribute video frame has at least one raw patch including one of 3DGS scale values, 3DGS rotation values, a 3DGS transparency value, 3DGS color values, or 3DGS spherical harmonic values.

At step 1216, the compressed bitstream is transmitted to another apparatus, such as via a communication interface like the communication interface 220 of FIG. 2 or the RF transceiver 310, the TX processing circuitry 315, and/or the RX processing circuitry 325 of FIG. 3. In some embodiments, the output compressed bitstream can be transmitted to an external device or to a storage on the electronic device 300.

Although FIG. 12 illustrates one example of an encoding method 1200, various changes may be made to FIG. 12. For example, while shown as a series of steps, various steps in FIG. 12 may overlap, occur in parallel, or occur any number of times.

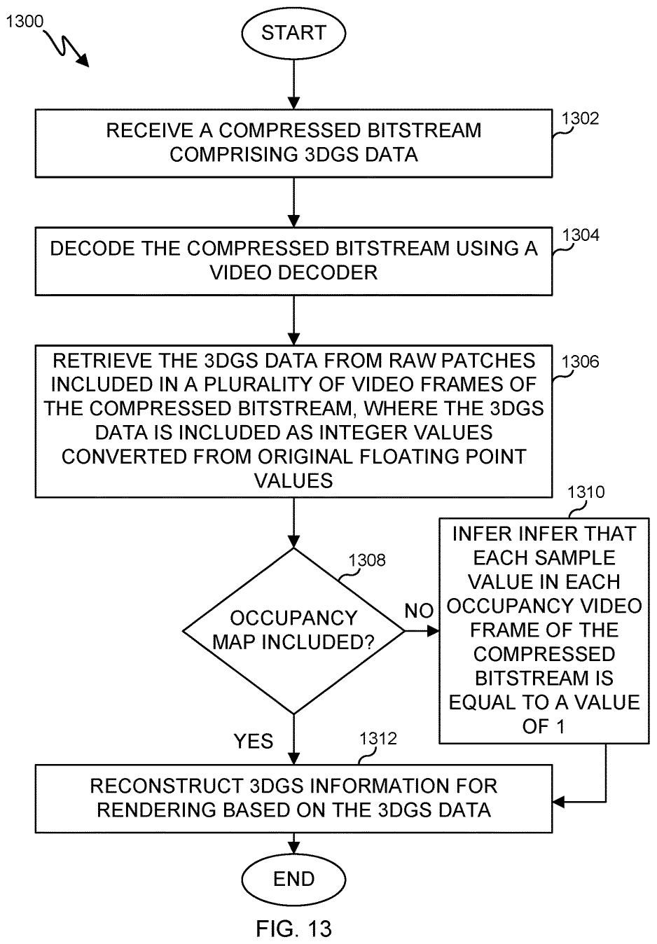

FIG. 13 illustrates an example decoding method 1300 in accordance with this disclosure. For ease of explanation, the method 1300 of FIG. 13 is described as being performed using the electronic device 300 of FIG. 3. However, the method 1300 may be used with any other suitable system and any other suitable electronic device.

As shown in FIG. 13, at step 1302, a compressed bitstream is received including 3DGS data, such as via a communication interface like the communication interface 220 of FIG. 2 or the RF transceiver 310, the TX processing circuitry 315, and/or the RX processing circuitry 325 of FIG. 3. At step 1304, the compressed bitstream is decoded using a video decoder. For example, the compressed bitstream can be decoded/de-compressed using a V-PCC video decoder to get and unpack the decoded video frames. At step 1306, the 3DGS data is retrieved from raw patches included in a plurality of video frames of the compressed bitstream, where the 3DGS data is included as integer values converted from original floating point values, as described with respect to FIG. 4. At step 1308, it is determined whether an occupancy map is not included in the compressed bitstream. If not, at step 1310, based on the determination, it is inferred that each sample value in each occupancy video frame of the compressed bitstream is equal to a value of 1. The method 1300 then moves to step 1312. If, at step 1308, it is determined that one or more occupancy maps are included in the compressed bitstream, the method also moves to step 1312 to proceed with the decoding process as normal.

As described in this disclosure, in various embodiments, the plurality of video frames can include a geometry video frame, and a raw patch of the geometry video frame can include x, y, and z coordinates of the 3DGS data. As described in this disclosure, in various embodiments, the x, y, and z coordinates of the 3DGS data in the raw patch of the geometry video frame can correspond to all 3D Gaussians in a 3DGS frame. As described in this disclosure, in various embodiments, a 3D space associated with the 3DGS data can be divided into cubes. As described in this disclosure, in various embodiments, the plurality of video frames can include a geometry video frame, the geometry video frame can include a plurality of raw patches, and each raw patch of the plurality of raw patches can include data for one of the cubes. As described in this disclosure, in various embodiments, the plurality of video frames can include attribute video frames, where each attribute video frame can have a raw patch including one of 3DGS scale values, 3DGS rotation values, a 3DGS transparency value, 3DGS color values, or 3DGS spherical harmonic values.

At step 1312, 3DGS information is reconstructed for rendering based on the 3DGS data. In various embodiments, the electronic device 300 can output the decoded content using the reconstructed 3DGS, such as 3D video/images. The output decoded content can be transmitted to an external device, such as a display device, or to a storage device on the electronic device 300 or on another device, for example.

Although FIG. 13 illustrates one example of a decoding method 1300, various changes may be made to FIG. 13. For example, while shown as a series of steps, various steps in FIG. 13 may overlap, occur in parallel, or occur any number of times.

Although the present disclosure has been described with exemplary embodiments, various changes and modifications may be suggested to one skilled in the art. It is intended that the present disclosure encompass such changes and modifications as fall within the scope of the appended claims. None of the description in this application should be read as implying that any particular element, step, or function is an essential element that must be included in the claims scope. The scope of patented subject matter is defined by the claims.

What is claimed is:

1. An apparatus comprising:
a communication interface configured to receive a compressed bitstream comprising 3D Gaussian Splats (3DGS) data; and
a processor operably coupled to the communication interface, wherein the processor is configured to:
decode the compressed bitstream using a video decoder;
retrieve the 3DGS data from raw patches included in a plurality of video frames of the decoded compressed bitstream, wherein the 3DGS data is included as integer values converted from original floating point values; and
reconstruct 3DGS information for rendering based on the 3DGS data.

2. The apparatus of claim 1, wherein the plurality of video frames includes a geometry video frame, and wherein a raw patch of the geometry video frame includes x, y, and z coordinates of the 3DGS data.

3. The apparatus of claim 2, wherein the x, y, and z coordinates of the 3DGS data in the raw patch of the geometry video frame correspond to all 3D Gaussians in a 3DGS frame.

4. The apparatus of claim 1, wherein a 3D space associated with the 3DGS data is divided into cubes.

5. The apparatus of claim 4, wherein:
the plurality of video frames includes a geometry video frame;
the geometry video frame includes a plurality of raw patches; and
each raw patch of the plurality of raw patches includes data for one of the cubes.

6. The apparatus of claim 1, wherein the plurality of video frames includes attribute video frames, and wherein each attribute video frame has a raw patch including one of:
3DGS scale values;
3DGS rotation values;
a 3DGS transparency value;
3DGS color values; or
3DGS spherical harmonic values.

7. The apparatus of claim 1, wherein the processor is further configured to:
determine that an occupancy map is not included in the decoded compressed bitstream; and
based on the determination, infer that each sample value in each occupancy video frame of the decoded compressed bitstream is equal to a value of 1.

8. A method comprising:
receiving a compressed bitstream comprising 3D Gaussian Splats (3DGS) data;
decoding the compressed bitstream using a video decoder;
retrieving the 3DGS data from raw patches included in a plurality of video frames of the decoded compressed bitstream, wherein the 3DGS data is included as integer values converted from original floating point values; and
reconstructing 3DGS information for rendering based on the 3DGS data.

9. The method of claim 8, wherein the plurality of video frames includes a geometry video frame, and wherein a raw patch of the geometry video frame includes x, y, and z coordinates of the 3DGS data.

10. The method of claim 9, wherein the x, y, and z coordinates of the 3DGS data in the raw patch of the geometry video frame correspond to all 3D Gaussians in a 3DGS frame.

11. The method of claim 8, wherein a 3D space associated with the 3DGS data is divided into cubes.

12. The method of claim 11, wherein:
the plurality of video frames includes a geometry video frame;
the geometry video frame includes a plurality of raw patches; and
each raw patch of the plurality of raw patches includes data for one of the cubes.

13. The method of claim 8, wherein the plurality of video frames includes attribute video frames, and wherein each attribute video frame has a raw patch including one of:
3DGS scale values;
3DGS rotation values;
a 3DGS transparency value;
3DGS color values; or
3DGS spherical harmonic values.

14. The method of claim 8, further comprising:
determining that an occupancy map is not included in the decoded compressed bitstream; and
based on the determination, inferring that each sample value in each occupancy video frame of the decoded compressed bitstream is equal to a value of 1.

15. An apparatus comprising:
a communication interface; and
a processor operably coupled to the communication interface, the processor configured to:
retrieve 3D Gaussian Splats (3DGS) data for compressing into a compressed bitstream;
convert floating point values of the 3DGS data into integer values;
pack the integer values of the 3DGS data into raw patches included in a plurality of video frames;
generate, by a video encoder using the plurality of video frames, the compressed bitstream comprising the 3DGS data; and
transmit, via the communication interface, the compressed bitstream to another apparatus.

16. The apparatus of claim 15, wherein the plurality of video frames includes a geometry video frame, and wherein a raw patch of the geometry video frame includes x, y, and z coordinates of the 3DGS data.

17. The apparatus of claim 16, wherein the x, y, and z coordinates of the 3DGS data in the raw patch of the geometry video frame correspond to all 3D Gaussians in a 3DGS frame.

18. The apparatus of claim 15, wherein:
a 3D space associated with the 3DGS data is divided into cubes;
the plurality of video frames includes a geometry video frame;
the geometry video frame includes a plurality of raw patches; and
each raw patch of the plurality of raw patches includes data for one of the cubes.

19. The apparatus of claim 15, wherein the plurality of video frames includes attribute video frames, and wherein each attribute video frame has a raw patch including one of:
3DGS scale values;
3DGS rotation values;
a 3DGS transparency value;
3DGS color values; or
3DGS spherical harmonic values.

20. The apparatus of claim 1, wherein the processor is further configured to generate the compressed bitstream without including an occupancy map, wherein the other apparatus infers, based on a lack of the occupancy map in the compressed bitstream, that each sample value in each occupancy video frame of the compressed bitstream is equal to a value of 1.
